(19) United States
(12) Patent Application Publication
(10) Pub. No.: US 2013/0214619 A1
(43) Pub. Date: Aug. 22, 2013

(54) METHOD AND DEVICE FOR MECHANICAL ENERGY HARVESTING

(71) Applicants: Balakrishnan Nair, Sandy, UT (US); Zachary Murphree, Salt Lake City, UT (US); Andrew Joseph Gill, Salt Lake City, UT (US); Jesse Alan Nachlas, Salt Lake City, UT (US)

(72) Inventors: Balakrishnan Nair, Sandy, UT (US); Zachary Murphree, Salt Lake City, UT (US); Andrew Joseph Gill, Salt Lake City, UT (US); Jesse Alan Nachlas, Salt Lake City, UT (US)

(73) Assignee: OSCILLA POWER INC., Salt Lake City, UT (US)

(21) Appl. No.: 13/593,369

(22) Filed: Aug. 23, 2012

Related U.S. Application Data
(63) Continuation-in-part of application No. 13/361,806, filed on Jan. 30, 2012.
Application No. 13/361,806 is a continuation-in-part of application No. 13/541,250, filed on Jul. 3, 2012.
(60) Provisional application No. 61/526,640, filed on Aug. 23, 2011.

(51) Int. Cl. H01L 41/12

(52) U.S. Cl. CPC H01L 41/125
USPC 310/17; 310/26

(57) ABSTRACT

An apparatus for harvesting electrical power from mechanical energy is described. The apparatus includes at least one magnetostrictive element, at least one electrically conductive coil or circuit, and a magnetic circuit coupled to the electrically conductive coil or circuit to increase or maximize power production. The magnetostrictive element is configured to experience a forced stress and strain in response to external mechanical excitations. The electrically conductive coil or circuit is configured to produce electrical energy through electromagnetic induction.

### CROSS-REFERENCE TO RELATED APPLICATIONS

This application claims the benefit of U.S. Provisional Application No. 61/526,640, filed on Aug. 23, 2011 (docket no. OSC-P012P). This application is a continuation-in-part of U.S. application Ser. No. 13/361,806, filed on Jan. 30, 2012 (docket no. OSC-P008). This application is a continuation-in-part of U.S. application Ser. No. 13/541,250, filed on Jul. 3, 2012 (docket no. OSC-P006C1). Each of these applications is incorporated by reference herein in its entirety.

### BACKGROUND

Many types of mechanical energy harvesters are known in the literature. Two of the common types include harvesters that utilize magnets that move relative to conductive coils so as to generate an induced current and/or voltage within the coils, and harvesters that utilize piezoelectric elements that undergo stress changes resulting in electric current and/or voltage in these elements.

While viable for very small scale power production, both of these approaches have specific difficulties in scaling up to power levels of 0.1 W or above, and more specifically 1 W or above, especially if such power production is to be maintained across a wide-range of vibration frequencies.

Moving magnet designs depend on significant relative motion to be able to produce significant power. At the high frequency (about 10-500 Hz), which represents a moderate acceleration (1-10 Gs) vibration environment typical of many types of machinery, the high displacements needed to make watts (i.e., one watt or more) of power are difficult to achieve in moving magnet designs. Further, if more powerful magnets are used to increase power density, cogging forces/torques become difficult to overcome and structural stiffness requirements become exceedingly more demanding.

Piezoelectrics, being semiconducting ceramics, have intrinsic issues related to high internal resistance and/or high internal impedance, and low structural reliability that prevent them from being usefully scaled up for broad band power generation of the order of even watts (i.e., one watt or more) and have thus been largely limited to the micro-watt to milli-watt ranges.

Efforts to study the potential of power generation using magnetostrictive materials have demonstrated the energy harvesting potential of giant magnetostrictive materials such as galfenol (an iron gallium alloy) and Terfenol-D. Efforts have validated models for magnetostrictive power generation by conducting experiments on rods of giant magnetostrictive materials such as Terfenol-D and galfenol that demonstrated power production on the order of hundreds of watts at very high frequencies (about 500-1000 Hz). The particular designs studied had poor power density and used a significant volume of permanent magnets relative to the volume of magnetostrictive alloy designs that are not attractive from a power density, cost or manufacturability standpoint.

Cantilevers of Metglas® have been used to harvest vibration energy. Metglas layers were deposited on a structural support and the entire structure was wrapped in a conductive coil. This design is non-ideal as the area contained within the coil is significantly greater that the area of cross-section of the Metglas alloy, resulting in a coil internal resistance that is significantly higher than needed. Further, the design does not allow for magnetic biasing or pre-stressing of the magnetostrictive elements, both of which are well-recognized ways of enhancing the power density of magnetostrictive energy harvesters. Additional work has resulted in methods and designs for improved power density and power production using low cost magnetostrictive alloys specifically for wave energy applications.

### SUMMARY

Embodiments of an apparatus for harvesting electrical power from mechanical are described. The apparatus includes at least one magnetostrictive element, at least one electrically conductive coil or circuit, and a magnetic circuit coupled to the electrically conductive coil or circuit to increase or maximize power production. The magnetostrictive element is configured to experience a forced stress and strain in response to external mechanical excitations. The coil or circuit is configured to produce electrical energy through electromagnetic induction.

Other aspects and advantages of embodiments of the present invention will become apparent from the following detailed description, taken in conjunction with the accompanying drawings, illustrated by way of example of the principles of the invention.

### BRIEF DESCRIPTION OF THE DRAWINGS

FIG. 1 depicts an embodiment of an apparatus for harvesting electrical power for use in a downhole drill-string.

FIG. 2 depicts the predicted power output under compressive load changes.

FIG. 3 depicts one embodiment of an apparatus for harvesting electrical power from mechanical energy.

FIG. 4 depicts one embodiment of an apparatus for harvesting electrical power from mechanical energy and its use in a prosthetic limb.

FIG. 5 depicts the voltage output for a model input.

Throughout the description, similar reference numbers may be used to identify similar elements.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

Given the challenges described above, there remains an opportunity for mechanical energy harvesting devices that can make significant quantities of electric power (greater than about 0.1 Watts, and in some embodiments greater than about 1 Watt) from the vibrations inherent in various types of industrial equipment while being able to fit into available space for incorporation into or use with such equipment. One example of such an environment is downhole drilling where the available energy in drill string or drill collar vibrations has a moderate frequency (about 0-500 Hz, and more typically about 0-50 Hz, or even as low as 0-5 Hz) and moderate accelerations (about 0-20 G's, and more typically about 0-5 Gs). Typically, axial load changes (or axial vibrations) may occur at frequencies corresponding to the drill speed which is typically 0-250 revolutions per minute (RPM), which corresponds to about 0-4 Hz. Harmonics of these frequencies (e.g., 6 Hz or 9 Hz for a 180 RPM/3 Hz drilling speed) may also be available. Mechanical energy harvesting devices in this environment should be able to operate at high temperatures (as high as about 250° C., and more typically as high as about 175° C.). Further, some devices are able to make the required power across the various operating modes of the machinery (for example, different RPMs, weight on bit, etc. for drilling applications) which may include a significant variation in the range of frequencies and mechanical loads experienced. The loads experienced are often compressive loads as they are controlled in part by the weight of the drill-string above the specific location of interest. Other axial load changes are experienced due to “bit bounce” in the drill bit which is a mode of vibration experienced during the drilling operation. “Bit bounce” occurs when the drill bit experiences accelerations in the axial direction due to vibrations.

Some embodiments of improved methods and designs for harvesting electric power from mechanical load use low-cost magnetostrictive materials. In particular, some embodiments produce over 0.1 watts of electric power from mechanical vibrations. Other embodiments produce over 1 watt of electric power from mechanical vibrations.

Embodiments described herein include a mechanical energy harvester that can convert mechanical loads to electrical energy using magnetostrictive elements. Embodiments also include a method and device for converting mechanical loads in the bottom hole assembly (BHA) and/or drill string of drilling rigs, which could be used for drilling oil and gas wells or wells for geothermal energy systems.

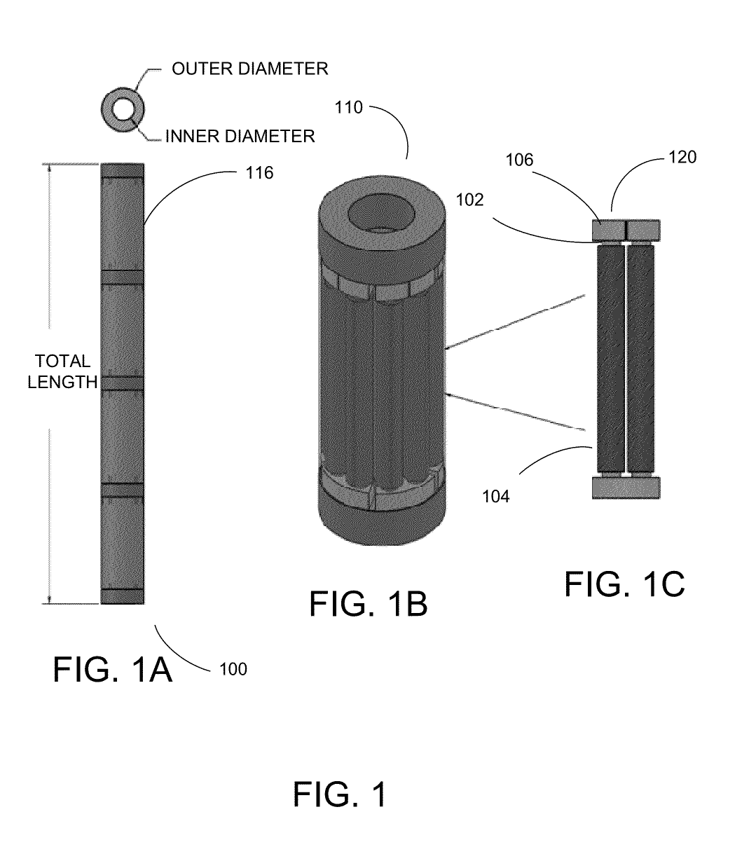

FIG. 1 depicts an embodiment of an apparatus for harvesting electrical power for use in a downhole drill-string 100. Embodiments herein facilitate harvesting energy from vibrations external to the device and generating electricity from this energy. In one embodiment, the device includes at least one magnetostrictive element 102 and one or more electrically conductive coils or circuits. The device also includes one or more magnetic circuits which are coupled with one or more electrical circuits to increase or maximize power production. The external mechanical excitations cause a forced stress and strain in the magnetostrictive elements 102, which are converted into electrical energy through electromagnetic induction.

One embodiment of this device is an electric power generator for use in an environment where mechanical load changes are present or can be produced. The embodiment includes a magnetostrictive rod assembly 120 with one or more magnetostrictive elements 102 which are oriented in such a way as to experience at least a part of the mechanical load changes experienced by a drill-string 100 (or other equipment); a coil assembly 104 in proximity to magnetostrictive alloy material; a source 106 of magnetomotive force (MMF), including permanent magnet material and/or electromagnets.

One or more magnetostrictive elements may be arranged to enable magnetic coupling between them. The magnetostrictive elements also may be arranged to form a substantially closed magnetic circuit, with minimal air gaps. The magnetostrictive elements may be incorporated into a downhole tool 110 specifically designed primarily for electrical power generation, or may be may be designed to be incorporated into other downhole tools to provide at least a portion of the power required by such tools or to charge rechargeable batteries so as to extend the time that the batteries can be used before requiring them to be recharged by other methods.

The mechanical load alters the magnetic characteristics of the magnetostrictive elements, which results in electromagnetic induction of a voltage in the coil assembly 104.

The rod assembly (and separate magnetostrictive elements) may comprise a separate downhole tool for power production, or may be incorporated into new or existing downhole tools in the BHA or drill string. The specific geometry and location of the beam supports used may impact the locations, magnitude, and directions, of rod stresses and power production, but in no way limit the overall scope of this invention.

In some embodiments, the device may comprise multiple rods and may be built in a configuration that it occupies an annular space as shown in FIG. 1B. This geometry has the benefit that the drilling fluid (mud) can flow inside the cylindrical bore of the device, which is highly desirable for downhole tools. As shown, the device incorporates multiple flux paths each of which includes two magnetostrictive rods and at least one MMF source, preferably a rare earth permanent magnet that can survive the high-temperature downhole operating environment without a significant degradation in performance.

Further, some embodiments include reliable packaging or casing 116 which will not only protect the internal components of the device from hot corrosive liquids and gases, as well as from drilling mud and any other constituents of the operating environment.

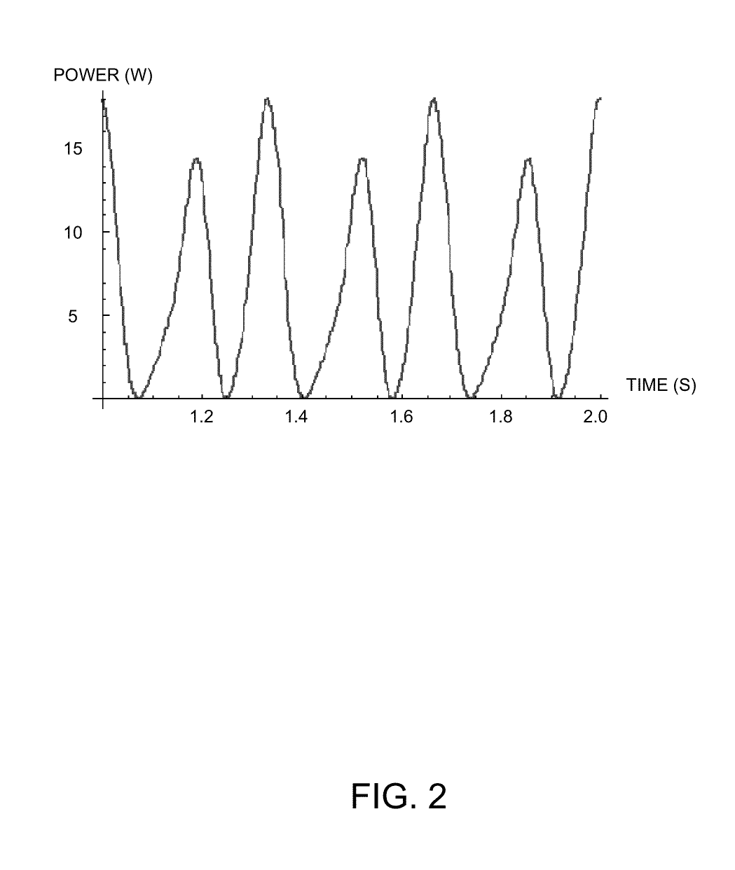

FIG. 2 depicts the predicted power output under compressive load changes. Detailed electromagnetic performance modeling of this configuration indicates that this tool as shown could make approximately 7 Watts of average power when subjected to sinusoidal compressive load changes of 500 to 5000 lbs at 3 Hz at 150° C. The predicted power output under these conditions is shown in FIG. 2.

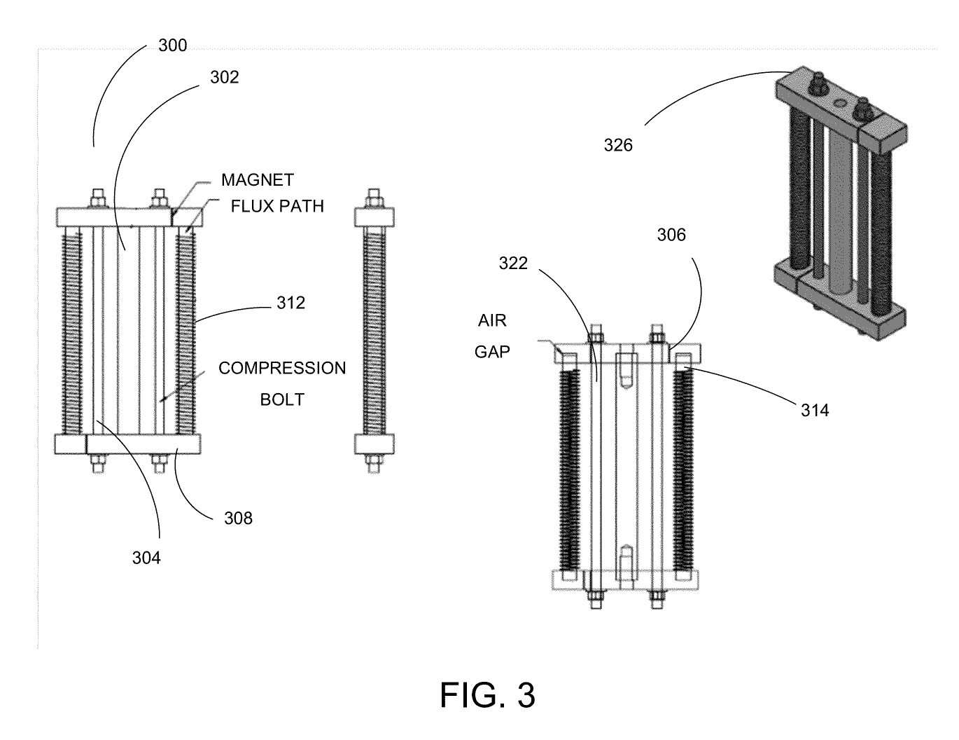

FIG. 3 depicts one embodiment of an apparatus 300 for harvesting electrical power from mechanical energy. In some embodiments, the magnetostrictive elements 302 are in a state of stress (termed “pre-stress”) in the static configuration which may be held in place by a compression bolt 304. This pre-stress may enhance or optimize the change in magnetic characteristics caused by mechanical load changes, especially if at least a portion of the load changes experienced are in tension.

In some embodiments, the arrangement of the magnetostrictive elements 302, MMF source 306, and mass assembly 308 form a closed magnetic circuit. This closed magnetic circuit may enhance or maximize the initial magnetic flux and magnetic characteristic changes due to the mechanical load changes.

A particular embodiment of this device includes at least one magnetostrictive element within a rod based assembly. The individual magnetostrictive elements may be conceptualized as individual rods (with lengthwise dimensions that are substantially greater than cross-sectional dimensions). The magnetostrictive element may have any length or cross-sectional geometry. In some preferred embodiments, the beam will have a substantially cylindrical geometry. In an embodiment in which the cross-section of the magnetostrictive elements is rectangular, the longer dimension of the rectangular prism is approximately parallel to the direction of dominant load changes.

Some embodiments of the device contain more than one magnetostrictive element. In some embodiments, two or more magnetostrictive elements may form part of the magnetic circuit and share the mechanical load changes as shown in FIG. 1C, which may result in a greater magnetic circuit reluctance change than if each of the rods were part of separate magnetic circuits, the net effect being that the flux density changes experienced by each rod (and therefore the energy production from each rod) is greater for such embodiments.

In some embodiments, coils 312 may be wrapped around each magnetostrictive element 302 individually such that the coils pass through the space between the magnetostrictive elements. As mentioned above, the magnetostrictive elements may form separate parts of a substantially closed (i.e., without substantial air gaps) magnetic circuit, which could be completed at both ends of the structure by magnetically permeable materials and/or magneto-mechanical force (MMF) sources 306 (e.g., permanent magnet material, electromagnets, etc.). In some embodiments, these materials would be placed in the gap at both ends of the magnetostrictive elements to form a closed flux path.

In some embodiments, the magnetostrictive elements may be magnetically coupled with external flux path members 314 that have coils 312 around them. The changes in stress/strain in the magnetostrictive elements result in changes in flux in the magnetostrictive elements, as well as in the external flux path members, and coils 312 may be placed around the external flux path members and/or the magnetostrictive elements so that the changes in magnetic flux can result in an induced current/voltage in these coils. This design allows for the length of the flux path and/or the number of turns of coil to be significantly greater than if coils are wound around the magnetostrictive elements only. Further, the average diameter (or significant dimensions) of each turn of coil may be smaller in this configuration than if the coils are wound around the magnetostrictive elements alone. This can result in a lower device internal resistance for a certain number of turns of coil, and consequently higher power density. This embodiment is illustrated in FIG. 3.

One possible application of the device is to provide electric power in remote locations. Some embodiments of the device may be configured as a downhole power source for electronic equipment in drilling or well formation/completion applications, or for trickle charging batteries or other energy storage devices. In some embodiments, multiple devices may be housed inside a single enclosure. Each device could be designed such that its mechanical load experienced and power signature is slightly different from the other devices in the enclosure, which would allow for more power production across a range of vibration frequencies. The orientation of each device could also be varied in order to capture the energy from load changes in many directions. In another embodiment, one or more of the rod assemblies may be oriented at a different angle with respect to the radii of the pipe. For example, in one embodiment, the rod assemblies may be rotated approximately 90 degrees from the illustrated position so that any load changes in the radial direction may be captured. In another example, some of the beam assemblies may be aligned with radial directions while other beam assemblies are aligned with annular directions. Each device may be magnetically isolated from the other devices and the enclosure in order to maintain the integrity of the magnetic circuit.

Some embodiments may be particularly useful in mounting around drill strings, drill collars, etc. Some embodiments of the device may be used in combination with and/or integrated into other devices/tools used downhole. These tools/devices may be located on the bottom hole assembly (BHA). These tools/devices may include, without limitation, measurement while drilling (MWD) tools, logging while drilling (LWD) tools, power packs, acoustic and/or electromagnetic signal generators, acoustic and/or electromagnetic signal boosters, acoustic and/or electromagnetic signal transmitters/repeaters, and so forth.

The device may also include or be used in combination with power electronics to convert the output electrical energy into a more desirable form. These electronics may include, without limitation, capacitive reactive power correction, single and/or poly-phase rectification (active and or passive), voltage regulation, voltage multipliers and/or transformers for increasing or decreasing voltage, buck, boost or buck-boost converters, voltage and/or current modulation, and other subcomponents.

Some embodiments of this device are particularly suitable to use with low cost magnetostrictive alloys, and do not require the use of the more expensive, supply-limited giant magnetostrictive materials that have terbium or gallium as part of their composition. Some embodiments of this device utilize metal alloys where iron and aluminum are the main constituents as the magnetostrictive elements. Some embodiments of the device utilize metal alloys that contain iron and aluminum where the iron atomic weight % is at least 75% and the aluminum atomic weight % is at least 2%. More specifically, some embodiments of the device utilize metal alloys that contain iron and aluminum where the iron atomic weight % is at least 80% and the aluminum atomic weight % is at least 12%. More specifically, some embodiments of the device utilize metal alloys that contain iron and aluminum where the iron atomic weight % is 81-83% and the aluminum atomic weight % is 17-19%.

In some embodiments, the conductive coil may be wound directly on the magnetostrictive elements. In some other embodiments, the coil may be designed such that there is some clearance between each magnetostrictive element and the corresponding coil, where the Poisson's strain of the magnetostrictive element can be accommodated. In some embodiments, the coil may be mechanically coupled to the magnetostrictive elements or the external packaging with bonding materials or fixtures, which may include without limitation screws, bolts, epoxies (e.g., high temperature epoxies) or other adhesives or other methods familiar to those skilled in the art.

In some embodiments, the magnets are rare earth permanent magnets with ability to operate at higher temperatures. In some embodiments, particular grades of rare earth Nd—Fe—B permanent magnets that can operate up to 200° C. may be used (for instance “NEH”). In some embodiments, samarium-cobalt based rare earth permanent magnets that can be used up to 300° C. may be used.

Since the cross-sectional area of the magnetostrictive elements is small compared with the length, care must be taken not to have the magnetomotive force MMF too high or flux path magnetic reluctance too low so as to saturate all or some of the flux path components. The magnetomotive force MMF may be lowered by any number of methods, including without limitation, using magnets with reduced thickness (or reduced volume) or using different magnet materials with lower coercivity. The circuit reluctance may be adjusted by using any number of methods, including without limitation, using materials in the flux path with relatively low relative magnetic permeability (e.g., steels with relatively permeability lower than 100), introducing very small air gaps or spacers of very small thickness and extremely small relative permeability (e.g., aluminum).

Since magnetostrictive alloy materials generally have less mechanical strength and fracture toughness relative to structural alloys, some embodiments are made using manufacturing processes and designs that can result in enhanced component reliability during operation. These techniques may include, without limitation, hot/cold rolling (or otherwise mechanically working) the magnetostrictive elements during manufacturing or pre-compressing the magnetostrictive elements to a load level where the stress will never become tensile (or exceed a design stress target) during operation.

In addition to providing enhanced reliability, pre-stressing can also provide enhanced mechano-magnetic performance and therefore enhanced power densities. Therefore, some embodiments of the device may incorporate some form of pre-compression of the alloy materials in the beam. This may be done by any number of methods. As one example, this may be accomplished by mechanical pre-stressing or thermal pre-stressing. Mechanical pre-stressing may be accomplished through the use of compression fixtures or a structural plate 326 in which the alloy is tightened down using bolts 322. Thermal pre-stressing may be accomplished by incorporating the rod into an external loading fixture at an elevated temperature above the expected temperature of operation. When the fixture is at the effective temperature of operation, the rod will therefore be in compression and by designing the geometry of the fixture relative to the rod, a design target stress can be attained.

Rare earth permanent magnet materials, being non-structural ceramics, are intrinsically brittle and have low fracture toughness. Therefore, some embodiments of the device incorporate design features that will allow the magnet materials to be packaged so that they can survive mechanical shock and vibration. This may be accomplished by any number of methods, including without limitation methods by which the magnets may be compressed down using soft and/or ductile materials.

There are other methods of applying loads onto a magnetostrictive material. For example, using a cantilever as a loading mechanism for a magnetostrictive rod. In such a device, at least one magnetostrictive rod may be one of the supports of a cantilever beam with a mass, that may oscillate when subjected to a vibrating environment, at some distance away along the length of the cantilever. Such a device can be made more efficient by combining it with various designs and methods of magnetostrictive power generation including a substantially closed flux path, pre-compression of the rods and permanent magnets included in the flux path, including specifically methods and devices described in U.S. Provisional Patent Application Nos. 61/437,586, 61/328,396, and U.S. patent application Ser. Nos. 13/016,828 and 13/016,895 (all of these are incorporated by reference herein in their entirety). A closed flux path with two magnetostrictive rods that share the load also may be a design that is compatible with some operating conditions and environments.

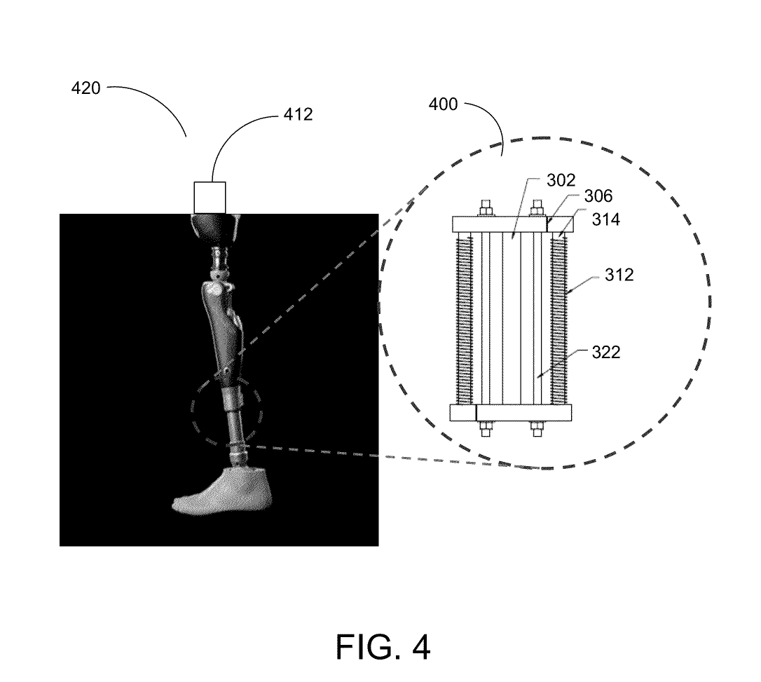

FIG. 4 depicts one embodiment of an apparatus for harvesting electrical power from mechanical energy 400 and its use in a prosthetic limb 420. Newer generations of prostheses include sensors, actuators, etc., that consume electrical energy. These are generally powered by an onboard battery, but this concept would either replace the battery or extend its operating life by providing an auxiliary energy source. The act of walking and running impart significant loads to the structural components of the prosthetic, with running causing a force of over 2000 N at 3 Hz. The force-time curve consists of discrete half-sine impacts with durations of around 200 ms, and these impacts occur at a frequency approaching 4 hz. By sizing a magnetostrictive device 400 appropriately and incorporating it as a structural component of the prosthesis 420, power could be generated from the everyday activities of the wearer to power the onboard electronics 412.

The device could consist of a pair or multiple pairs of magnetostrictive rods 302 that form a complete magnetic circuit (including additional flux path material and source(s) of biasing magnetic field(s)) that are then incorporated into the load path that is functionally the same as the tibia and fibula. The ground reaction force of each foot strike would then be transferred through the device, and a voltage would be induced in the coil surrounding each rod. This electrical energy could then be conditioned with power electronics to be used immediately by onboard electronics or stored in electrical energy devices (e.g. battery bank, capacitor, etc.) for future use.

To achieve a stress of 80 MPa in the magnetostrictive rod, the diameter of the rod would need to be on the order of 0.25″ for a load of 450 lbf (2000 N). If the load is shared between two rods, the diameter will be smaller than this. To avoid buckling, the length of each rod should be limited, but the length of the device (and therefore its power capacity) can be increased by having several individual modules mechanically in series.

Initial modeling of the performance of such a device suggests that useful amounts of power can be generated. If the 500 lbf load change is split between two magnetostrictive rods that are each 0.25″ in diameter (making up a single device), and there are two of these devices in series mechanically, the power output is predicted to be about 600 μW.

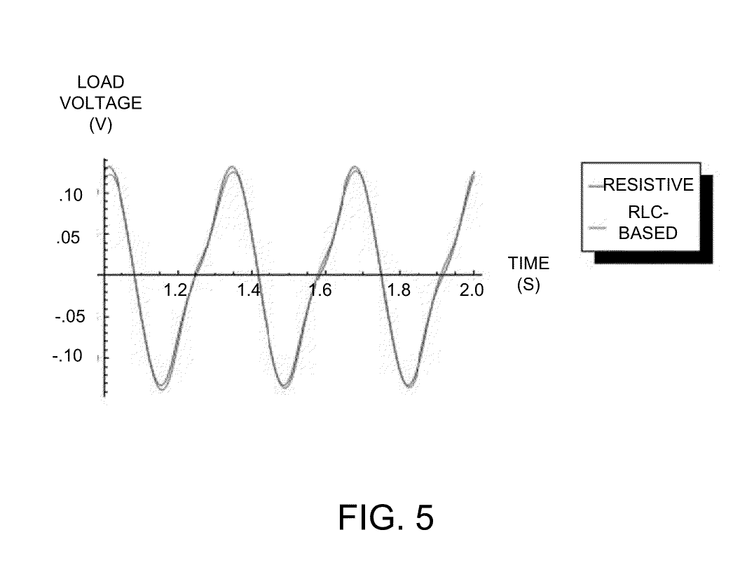

FIG. 5 depicts the voltage output for a model input. The inputs are a 28 AWG wire, a rod OD of 0.25″, a rod length of 3″, a coil OD of 0.5″, 4 rods, a coil resistance of 9.7852, a load resistance of 48.9352, a max load per rod of 250 lbf, a minimum load per rod of 0 lbf, a frequency of 3 Hz, a capacitance of 5.579 mF, an alloy weight of 0.0695 kg, a copper weight of 0.1324 kg, an average power per rod of 152 μF, and an average power per device of 609 μF. The sample voltage output is shown in FIG. 5.

In the above description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. An apparatus for harvesting electrical power from mechanical energy, the apparatus comprising:
at least one magnetostrictive element, wherein the magnetostrictive element is configured to experience a forced stress and strain in response to external mechanical excitations;
at least one electrically conductive coil or circuit, wherein the coil or circuit is configured to produce electrical energy through electromagnetic induction; and
a magnetic circuit coupled to the electrically conductive coil or circuit to increase or maximize power production.

2. The apparatus for harvesting electrical power from mechanical energy of claim 1, wherein the magnetic circuit comprises the magnetostrictive element, a source of magnetomotive force, and a mass assembly and the magnetic circuit is closed.

3. The apparatus for harvesting electrical power from mechanical energy of claim 1, the apparatus further comprising an external flux path member magnetically coupled with the magnetostrictive element.

4. The apparatus for harvesting electrical power from mechanical energy of claim 3, wherein the electrically conductive coil is placed around the external flux path member.

5. The apparatus for harvesting electrical power from mechanical energy of claim 1, wherein the electrically conductive coil is placed around the magnetostrictive element.

6. The apparatus for harvesting electrical power from mechanical energy of claim 1, the apparatus further comprising a corrosion resistant, water-tight casing.

7. The apparatus for harvesting electrical power from mechanical energy of claim 1, wherein the magnetostrictive element is pre-stressed in compression.

8. The apparatus for harvesting electrical power from mechanical energy of claim 7, wherein the pre-stressed magnetostrictive element is pre-stressed using other mechanical components.

9. The apparatus for harvesting electrical power from mechanical energy of claim 7, wherein the pre-stressed magnetostrictive element is pre-stressed using structural plates that are tightened down onto the magnetostrictive element using a compression bolt.

10. The apparatus for harvesting electrical power from mechanical energy of claim 1, the apparatus further comprising a magnet placed in a flux path.

11. The apparatus for harvesting electrical power from mechanical energy of claim 1, wherein the apparatus is placed within a downhole drill-string and the magnetostrictive element is oriented in such a way as to experience at least a part of mechanical load changes experienced by the drill-string.

12. The apparatus for harvesting electrical power from mechanical energy of claim 11, wherein two or more magnetostrictive elements are configured so that they occupy an annular space within the drill-string.

13. The apparatus for harvesting electrical power from mechanical energy of claim 12, wherein the electrically conductive coil is placed around each magnetostrictive element individually such that the coil passes through a space between the magnetostrictive elements.

14. The apparatus for harvesting electrical power from mechanical energy of claim 12, wherein the two or more magnetostrictive elements are arranged to form the closed magnetic circuit.

15. A method for harvesting electrical power from mechanical energy, the method comprising:
placing an apparatus in a downhole drill-string, wherein the apparatus comprises:
at least one magnetostrictive element, wherein the magnetostrictive element is configured to experience a forced stress and strain in response to external mechanical excitations, wherein the external mechanical excitations cause a change in magnetic flux;
at least one electrically conductive coil or circuit, wherein the coil or circuit is configured to produce electrical energy through electromagnetic induction; and
a magnetic circuit coupled to the electrically conductive coil or circuit to increase or maximize power production; and
using the change in magnetic flux to generate electrical power in the electrically conductive circuit.

16. The method for harvesting electrical power from mechanical energy of claim 15, wherein the magnetostrictive element is pre-stressed in compression.

17. The method for harvesting electrical power from mechanical energy of claim 16, wherein the pre-stressed magnetostrictive element is pre-stressed using other mechanical structural components.

18. The method for harvesting electrical power from mechanical energy of claim 17, wherein the magnetostrictive element has a bias magnetic field applied to it through the use of one or more magnets.

19. An apparatus for harvesting electrical power from mechanical energy, the apparatus comprising:
a prosthetic device having a structural member which incorporates a magnetostrictive element configured to experience stresses, wherein the stresses result in a change in magnetostrictive properties;
at least one electrically conductive coil or circuit coupled to the magnetostrictive element, wherein the coil or circuit is configured generate electrical power from the change in magnetostrictive properties; and
a magnetic circuit coupled to the electrically conductive coil or circuit to increase or maximize power production.

20. The apparatus of claim 19, the apparatus further comprising onboard electronics coupled to the prosthetic device, wherein the change in magnetostrictive properties generates electricity to supply electrical power to the onboard electronics.
